(19) United States
(12) Patent Application Publication
(10) Pub. No.: US 2026/0213748 A1
(43) Pub. Date: Jul. 23, 2026

(54) COUPLING OF QUANTUM DEVICES BY READOUT RESONATORS

(71) Applicant: IQM FINLAND OY, Espoo (FI)

(72) Inventors: Alpo VÄLIMAA, Espoo (FI); Caspar OCKELOEN-KORPPI, Espoo (FI)

(21) Appl. No.: 19/139,556

(22) PCT Filed: Dec. 5, 2023
(86) PCT No.: PCT/FI2023/050667

§ 371 Date: Jun. 16, 2025

(30) Foreign Application Priority Data
Dec. 16, 2022 (FI) 20226113

(51) Int. Cl. H03K 17/92

(52) U.S. Cl. CPC H03K 17/92

(57) ABSTRACT

There is provided an apparatus for simultaneous capacitive and inductive coupling between readout resonators and a transmission line comprising: a transmission line; at least one quantum device; and at least one readout resonator, wherein the at least one readout resonator is configured to couple the at least one quantum device to the transmission line based on a capacitive coupling and an inductive coupling.

### TECHNICAL FIELD

The present disclosure relates to a quantum electronic device and more particularly to coupling of readout resonators to a transmission line.

### BACKGROUND

In quantum computing, it has become common to use the term “qubit” to specify not only a basic unit of information but also an information storage element for storing one qubit of information. As an example, a superconductive processor may comprise one or more qubits (i.e. qubit-sized information storage elements). In such an example the qubit is an anharmonic oscillator, such as a transmon, and it may be coupled to an associated, or nearby, readout resonator for the readout of the state of the qubit stored therein.

In a multiqubit system or a quantum computer, several qubits are read through readout resonators that couple to a common readout transmission line shared over many such resonators. Each of these readout resonators have a specification or target coupling rate with the readout line. The readout line is a transmission line and subject to well defined nodes and maximum of voltage and current due to reflections from input capacitors or known elements. Also, other nonidealities contribute to the frequency-dependent positioning of the nodes and maxima due to other unpredicted sources of reflection or standing waves due to imperfections at the mismatching elements of the line or resonant modes of the sample holder, which can vary from a packaging of the sample to another, leading to unpredictable coupling rates.

The coupling rates of the readout resonator to the readout line are carefully adjusted by design for a given microwave circuit layout. This results in large coupling capacitance values of resonators close to the nodes of voltage along the transmission line. On the other hand, for inductive coupling, this results in large coupling inductance values of resonators close to the nodes of current along the transmission line. A small perturbation from the ideal environment can, however, dramatically change the situation, easily leading to excess coupling rates far from the specifications.

### SUMMARY

The scope of protection sought for various embodiments of the invention is set out by the independent claims. The embodiments, examples and features, if any, described in this specification that do not fall under the scope of the independent claims are to be interpreted as examples useful for understanding various embodiments of the invention.

It is an objective to overcome at least some of the problems identified above related to quantum computing.

According to a first aspect there is provided an apparatus, comprising:
a transmission line;
at least one quantum device; and
at least one readout resonator, wherein the at least one readout resonator is configured to couple the at least one quantum device to the transmission line based on a capacitive coupling and an inductive coupling.

According to a second aspect there is provided a quantum computing system comprising an apparatus according to an aspect.

According to a third aspect there is provided a method for an apparatus according to an aspect.

According to a fourth aspect there is provided a method for a quantum computing system according to an aspect.

At least some embodiments provide simultaneous capacitive and inductive coupling between a readout resonator and a transmission line.

### DESCRIPTION OF THE DRAWINGS

Other features and advantages of the invention will become apparent from the following description of a non-limiting example embodiment, with reference to the appended drawings, in which:

FIG. 1 illustrates a schematic example of a circuit for a quantum electronic device in accordance with at least some embodiments;

FIG. 2 illustrates a schematic example of a quantum computing system in accordance with at least some embodiments;

FIG. 3 illustrates examples of hybrid couplers in accordance with at least some embodiments; and

FIG. 4 illustrates an example of a method in accordance with at least some embodiments.

### DETAILED DESCRIPTION

In the following description, reference is made to the accompanying drawings, which form part of the disclosure, and in which are shown, by way of illustration, specific aspects in which the present disclosure may be placed. It is understood that other aspects may be utilized, and structural or logical changes may be made without departing from the scope of the present disclosure. The following detailed description, therefore, is not to be taken in a limiting sense, as the scope of the present disclosure is defined be the appended claims.

For instance, it is understood that a disclosure in connection with a described method may also hold true for a corresponding device or system configured to perform the method and vice versa. For example, if a specific method step is described, a corresponding device may include a unit to perform the described method step, even if such unit is not explicitly described or illustrated in the figures. On the other hand, for example, if a specific apparatus is described based on functional units, a corresponding method may include a step performing the described functionality, even if such step is not explicitly described or illustrated in the figures. Further, it is understood that the features of the various example aspects described herein may be combined with each other, unless specifically noted otherwise.

The following embodiments are exemplary. Although the specification may refer to “an”, “one”, or “some” embodiment(s) in several locations, this does not necessarily mean that each such reference is to the same embodiment(s), or that the feature only applies to a single embodiment. Single features of different embodiments may also be combined to provide other embodiments.

Use of ordinal terms such as “first,” “second,” “third,” etc., in the claims and description to modify a described feature does not by itself connote any priority, precedence, or order of one described feature over another or the temporal order in which acts of a method are performed, but are used merely as labels to distinguish one described feature having a certain name from another described feature having a same name (but for use of the ordinal term) to distinguish the described feature.

As used herein, “at least one of the following:” and “at least one of” and similar wording, where the list of two or more elements are joined by “and” or “or”, mean at least any one of the elements, or at least any two or more of the elements, or at least all the elements.

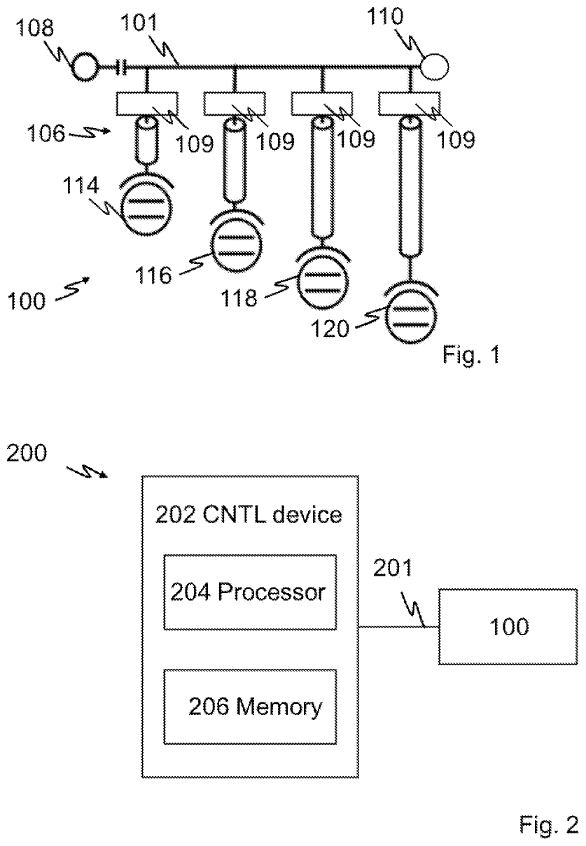

FIG. 1 illustrates a schematic example of a circuit 100 for a quantum electronic device. The circuit may be for a superconductive quantum processor. The circuit comprises quantum devices, e.g. quantum bits or qubits, 114, 116, 118, 120, and associated readout resonators 106 coupled, or connected, in series to a transmission line 101, or a probe line, for a readout of the quantum devices at a readout band. In an example, the readout resonators are configured to couple to the transmission line based on a capacitive coupling and an inductive coupling. In this way, simultaneous capacitive and inductive coupling of the readout resonators to the transmission line may be supported. When both capacitive and inductive coupling are used, issues resulting from large coupling capacitance values close to nodes of voltage at the transmission line and large coupling inductance values close to nodes of current at the transmission line may be alleviated. For example, a too large coupling capacitance or coupling inductance can cause decoherence, e.g. decays of qubit excitations to the transmission line. On the other hand, a too small coupling capacitance or coupling inductance can cause a slower qubit readout because it takes longer for the prober signal to excite the resonator. As a consequence, the readout error rate also increases, because the chance that the qubit decays through other channels before the readout is finished increases.

In an example in accordance with at least some embodiments, the quantum devices, or qubits, comprise superconducting qubits. Examples of the superconducting qubits comprise at least one of the following: a superconducting charge qubit; or a superconducting flux qubit; or a superconducting phase qubit. The superconducting qubits may be implemented by Josephson junctions.

In an example, the inductive coupling and capacitive coupling of each readout resonator to the transmission line causes that at the maxima of voltage in the transmission line, the capacitive coupling dominates and the other channel, i.e. the inductive channel, don't contribute to coupling. Close to the minima of voltage in the transmission line, the inductive coupling becomes dominant and the other channel, i.e. the capacitive channel don't contribute to coupling. In other words, at the maxima of current in the transmission line, the inductive coupling dominates and the other channel, i.e. the capacitive channel, don't contribute to coupling. Close to the minima of current in the transmission line, the capacitive coupling becomes dominant and the other channel, i.e. the inductive channel don't contribute to coupling.

In an example, the inductive coupling and capacitive coupling of each readout resonator to the transmission line may be provided by a hybrid coupler that is configured to couple the readout resonator of an individual quantum device to the transmission line. Accordingly, the hybrid coupler is paired with the quantum device and the associated readout resonator.

In an example, in accordance with at least some embodiments, each of the readout resonators 106 may be configured to have a coupling rate for capacitive coupling to the transmission line that is equal with a coupling rate for inductive coupling to the transmission line. In an example, the coupling rates may be provided by a hybrid coupler at each readout resonator. A mutual capacitance and inductance between each readout resonator and the transmission line may be evaluated such that the capacitive coupling and the inductive coupling have equal coupling rates, when operating in purely capacitive or inductive coupling regimes, or at voltage maxima or voltage minima of the transmission line. It should be noted that the coupling rate may be designed to have a balance between sufficiently fast readout (that is, sufficient coupling strength) and minimal coupling to the transmission line (to suppress qubit decay). Any deviation from the design parameter is considered as a degrade in performance and for this reason it is beneficial to meet the specifications at a wider range of possible voltage profiles along the transmission line.

In an example, during operation, one or more of the quantum devices 114, 116, 118, 120, may be excited. Excitation of a quantum device causes an electromagnetic waveform to an associated readout resonator 106. The excitation of the quantum device changes the effective resonance frequency of the associated readout resonator. Hence, an electromagnetic waveform close to the resonant frequency of the readout resonator is reflected with a different amplitude and/or phase depending on the state of the qubit. It should be noted that after the electromagnetic waveform has been reflected, the quantum device may remain excited. Therefore, the waveform has an electric field and a magnetic field that are coupled to the transmission line based on the capacitive coupling and the inductive coupling. A probe signal, or a readout waveform, may be fed, or coupled, to the transmission line at an input terminal 108 or port, arranged at one end of the transmission line for obtaining a readout signal at an output terminal 110. Each of the resonators of the quantum devices may have a different resonant frequency, such that frequencies of the probe signal may determine which quantum devices are actually read. The resulting readout signal comprises waveforms of the determined quantum devices at the readout band. Therefore, the readout band comprises multiplexed resonator frequencies that are dispersively coupled to the quantum devices. Phase of the readout signal may be used for detecting values of qubits from the readout signal. It should be noted that depending on implementation, the transmission line may be measured in transmission and/or in reflection of the probe signal for reading the values of the quantum devices.

In an example in accordance with at least some embodiments, each of the readout resonators 106 comprises a hybrid coupler 109 that is positioned at a readout resonator between a voltage maximum and a voltage minimum of a resonant mode of the readout resonator. In an example, the hybrid coupler is positioned close to, or at, a λ/8-operation point of the readout resonator, where λ is the wavelength of the readout resonator at a resonant frequency of the readout resonator.

In an example in accordance with at least some embodiments, the hybrid coupler 109 comprises at least one portion of the readout resonator 106 configured to couple an electric current to the transmission line 101 based on inductive coupling and at least one portion of the readout resonator 106 configured to couple a voltage to the transmission line based on capacitive coupling. In an example, the hybrid coupler may be formed by one or more portions of a readout resonator 306 and the hybrid coupler 109 comprises a loop next to the transmission line. The loop inductively couples the readout resonator with the transmission line, whereby an electromagnetic waveform of the readout resonator may be coupled to the transmission line. The hybrid coupler may further a have a geometry that supports capacitive coupling of the electromagnetic waveform to the transmission line. An example of the geometry is that at least one portion of the readout resonator 106 is configured to extend in a direction parallel with the transmission line. An example of the geometry is that the hybrid coupler has a section of the readout resonator sufficiently close to the transmission line for the capacitive coupling to the transmission line. It should be noted that the capacitive coupling further requires the resonant mode of the readout resonator to not be in a voltage node in the considered section of the conductor.

In an example, the quantum devices 114, 116, 118, 120, resonators 106 and the transmission line 101 can be made of superconductor materials. However, this is not an essential requirement, and other kinds of quantum technologies could be used. A superconductor material means here a material that can be made superconductive by cooling it to a sufficiently low temperature. An example of such materials is aluminum, but also other superconductor materials like molybdenum, niobium, tin, tantalum, or lead can be used. For operation, a superconductive quantum processor is cooled to a very low temperature, which can be some kelvins, or well under one kelvin, or in the order of some tens of millikelvins.

FIG. 2 illustrates a schematic example of a quantum computing system in accordance with at least some embodiments. The quantum computing system 200 comprises an apparatus and one or more control devices 202 that are operatively coupled 201 to one or more parts of the apparatus. The apparatus may comprise a circuit 100 described with FIG. 1. In the example, the control device may be coupled to a transmission line 101 and one or more quantum devices 114, 116, 118, 120 and the control device is configured to excite one or more of the quantum devices; to couple readout resonators of the excited one or more quantum devices 114, 116, 118, 120 to the transmission line 101 based on a capacitive coupling and an inductive coupling; to read a readout signal comprising waveforms of the excited one or more quantum devices at a readout band from the transmission line; and to determine, one or more values of qubits based on the readout signal. In an example, the control device is configured to feed a probe signal to the transmission line at an input terminal 108 of the transmission line and to read the readout signal from the transmission line at an output terminal 110 of the transmission line. In an example, couplings between the control device and the apparatus may be electrical connections. The couplings may provide readout control, qubit control, probe signal input and readout signal output, for example. It should be noted that in some embodiments a single terminal may serve for both input terminal and output terminal.

In an example, the control device 202 comprises at least one processor 204. The at least one processor 204 may include, for example, one or more various processing devices such as a coprocessor, a microprocessor, a control unit, a Digital Signal Processor (DSP), processing circuitry with or without an accompanying DSP, or various other devices including integrated circuits such as, for example, an Application Specific Integrated Circuit (ASIC), a Field Programmable Gate Array (FPGA), a microprocessor unit (MCU), a hardware accelerator, a special-purpose computer chip, or the like.

In an example, the control device 202 comprises at least one memory 206. The memory 206 may be configured to store, for example, one or more of probe signal(s), tuning signal(s), computer program code, computer program instructions and computer programs. Execution of the computer program code, computer program instructions and computer programs may cause at least one of the following for execution of one or more functionalities described herein: generating probe signal(s); or exciting one or more quantum devices; or generating tuning signal(s); coupling readout resonator to transmission line; or reading readout signal(s); or determining a state of a qubit based on the readout signal.

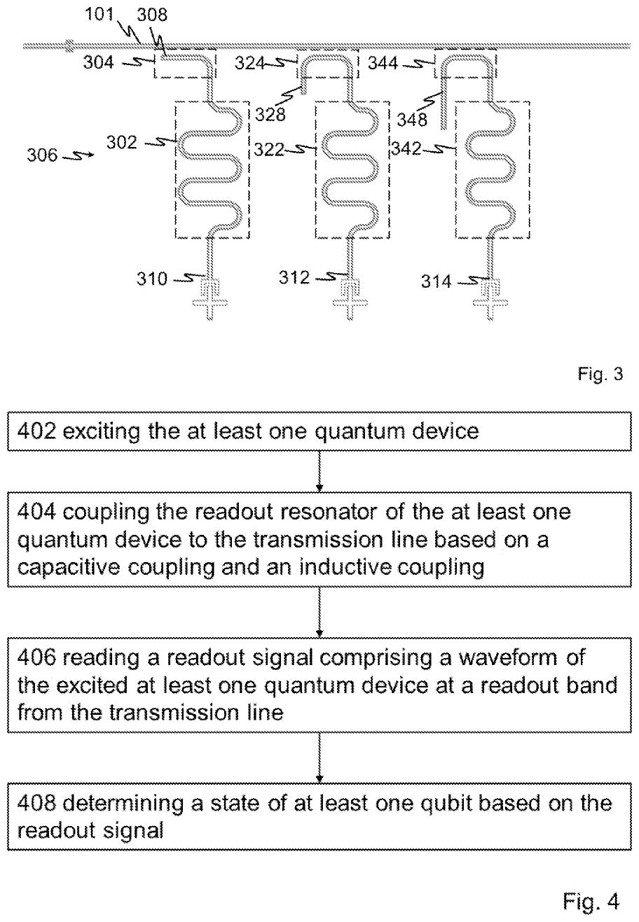

FIG. 3 illustrates examples of hybrid couplers in accordance with at least some embodiments. The hybrid couplers may be the hybrid couplers described with FIG. 1. The hybrid couplers provide capacitive coupling and inductive coupling of readout resonators 306 of the quantum devices 114, 116, 118, 120 to the transmission line 101. Each of the hybrid couplers may be formed by one or more portions of a readout resonator 306. The readout resonators are longitudinal electrical conductors that extend between a first end 310, 312, 314 coupled with a quantum device and a second end 308, 328, 348 that is closer to the transmission line than the first end.

In an example, in accordance with at least some embodiments, each of the hybrid couplers may comprise at least one portion 302, 322, 342 of the readout resonator configured to couple an electric current to the transmission line 101 based on inductive coupling and at least one portion 304, 324,344 of the readout resonator 106 configured to couple a voltage to the transmission line based on capacitive coupling. In an example, the at least one portion 302, 322, 342 of the readout resonator configured to couple an electric current to the transmission line 101 based on inductive coupling may be a loop next to the transmission line, whereby an electromagnetic waveform of the readout resonator may be coupled based on the inductive coupling to the transmission line. In an example, the at least one portion 304, 324, 344 of the readout resonator 106 configured to couple a voltage to the transmission line based on capacitive coupling may have a geometry that supports capacitive coupling of the electromagnetic waveform to the transmission line. An example of the geometry is that the at least one portion 304, 324, 344 is configured to extend in a direction parallel with the transmission line.

In an example, in accordance with at least some embodiments, the hybrid coupler 109 may be positioned close to, or at, a λ/8-operation point of the readout resonator, where λ is the wavelength of the readout resonator at a resonant frequency of the readout resonator. In this way the hybrid coupler may be positioned at the readout resonator between a voltage maximum and a voltage minimum of a resonant mode.

In an example, at least a portion of the hybrid coupler, for example a portion 304 of the readout resonator configured to couple a voltage to the transmission line based on capacitive coupling, may be positioned at a remote end 308 of the readout resonator with respect to the quantum device. Accordingly, the portion 304 of the readout resonator configured to couple a voltage to the transmission line based on capacitive coupling may be closer to the transmission line 101 than another end of the readout resonator that is coupled with the quantum device.

In another example, at least a portion of the hybrid coupler, for example the portion 324, 344 of the readout resonator configured to couple a voltage to the transmission line based on capacitive coupling and the portion 322,342 of the readout resonator configured to couple an electric current to the transmission line 101 based on inductive coupling, may be positioned away from the ends 328, 312, 348, 314 of the readout resonator. Accordingly, a total length of the readout resonator may be higher than a length of the hybrid coupler and a remote end 328, 348 of the readout resonator with respect to the quantum device may extend in a direction that is transverse to the direction of the transmission line 101, e.g. in a direction substantially away from the transmission line, whereby capacitive coupling between the remote end and the transmission line is reduced. Accordingly, the remote end 328, 348 may be closer to the transmission line 101 than another end 312, 314 of the readout resonator that is coupled with the quantum device. Additionally, the remote end 328, 348 of the readout resonator with respect to the quantum device may be substantially straight, or non-looped, whereby also inductive coupling between the remote end and the transmission line is reduced. Therefore, the capacitive coupling and the inductive coupling may be substantially provided by the hybrid coupler formed by the portions 322, 324, 342, 344 between the ends of the readout resonator. It should be noted that, a geometry of the end of the readout resonator coupled to the quantum device may be designed in a similar manner to the remote end for controlling capacitive and inductive coupling.

FIG. 4 illustrates an example of a method in accordance with at least some embodiments. The method provides simultaneous capacitive and inductive coupling. The method may be performed by a quantum computing system described with FIG. 2.

Phase 402 comprises exciting the at least one quantum device.

Phase 404 comprises coupling the readout resonator of at least one quantum device to the transmission line based on a capacitive coupling and an inductive coupling. In an example, the at least one quantum device is excited in phase 402.

Phase 406 comprises reading a readout signal comprising a waveform of the excited at least one quantum device at a readout band from the transmission line.

Phase 408 comprises determining a state of at least one qubit based on the readout signal.

In an example, the phases 402 to 406 may be performed by the quantum computing system described with FIG. 2.

In an example in accordance with at least some embodiments, there is provided a method for an apparatus, for example, the circuit 100 described with FIG. 1, or a part of the circuit, for example a hybrid coupler. The method provides simultaneous capacitive and inductive coupling and comprises the phase 404 of coupling the readout resonator of at least one quantum device to the transmission line based on a capacitive coupling and an inductive coupling. The apparatus for performing the method may comprise a transmission line; at least one quantum device; and at least one readout resonator, wherein the at least one readout resonator is configured to couple the at least one quantum device to the transmission line based on a capacitive coupling and an inductive coupling.

Any range or device value given herein may be extended or altered without losing the effect sought. Also, any embodiment may be combined with another embodiment unless explicitly disallowed.

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims and other equivalent features and acts are intended to be within the scope of the claims.

It will be understood that the benefits and advantages described above may relate to one embodiment or may relate to several embodiments. The embodiments are not limited to those that solve any or all of the stated problems or those that have any or all of the stated benefits and advantages. It will further be understood that reference to ‘an’ item may refer to one or more of those items.

Aspects of any of the embodiments described above may be combined with aspects of any of the other embodiments described to form further embodiments without losing the effect sought.

The term ‘comprising’ is used herein to mean including the method, blocks or elements identified, but that such blocks or elements do not comprise an exclusive list and a method or apparatus may contain additional blocks or elements.

It will be understood that the above description is given by way of example only and that various modifications may be made by those skilled in the art. The above specification, examples and data provide a complete description of the structure and use of exemplary embodiments. Although various embodiments have been described above with a certain degree of particularity, or with reference to one or more individual embodiments, those skilled in the art could make numerous alterations to the disclosed embodiments without departing from the spirit or scope of this specification.

### LIST OF REFERENCE SIGNS

| | |
|---|---|
| Circuit | 100 |
| Transmission line | 101 |
| Readout resonators | 106 |
| Transmission line terminals | 108, 110 |
| Quantum device | 114, 116, 118, 120 |
| Quantum computing system | 200 |
| Coupling(s) | 201 |
| Control device | 202 |
| Processor | 204 |
| Memory | 206 |
| Portion of readout resonator for inductive coupling | 302, 322, 342 |
| Portion of readout resonator for capacitive coupling | 304, 324, 344 |
| Readout resonator | 306 |
| End of readout resonator close to transmission line | 308, 328, 348 |
| End of readout resonator close to quantum device | 310, 312, 314 |
| Phases of the method of FIG. 4 | 402, 404, 406, 408 |

1. An apparatus, comprising:
a transmission line;
at least one quantum device; and
at least one readout resonator, wherein the at least one readout resonator is configured to couple the at least one quantum device to the transmission line based on a capacitive coupling and an inductive coupling, wherein the apparatus comprises:
more than one quantum devices and associated readout resonators configured to couple the quantum devices in succession along the transmission line based on a capacitive coupling and an inductive coupling; wherein each of the readout resonators comprises one end coupled with an associated quantum device and a remote end that is closer to the transmission line than the end at the associated quantum device, wherein the remote end closer to the transmission line is configured to extend in a direction that is transverse to the direction of the transmission line; wherein:
each of the readout resonators comprises hybrid coupler formed by a geometry of the readout resonator and said geometry comprises a first portion of the readout resonator configured to couple an electric current to the transmission line based on inductive coupling and a second portion of the readout resonator configured to couple a voltage to the transmission line based on capacitive coupling;
wherein at least a part of the readout resonators have a total length that exceeds a length of the hybrid coupler, whereby remote ends of the at least part of the readout resonators are configured to extend in a direction that is away from the transmission line and to have a geometry for reduced inductive and capacitive coupling to the transmission line.

2. The apparatus of claim 1, wherein the at least one readout resonator is configured to have a coupling rate for capacitive coupling to the transmission line that is equal with a coupling rate for inductive coupling to the transmission line.

3. The apparatus of claim 1, wherein the hybrid coupler is positioned at a readout resonator between a voltage maximum and a voltage minimum of a resonant mode of the readout resonator.

4. The apparatus of claim 3, wherein the hybrid coupler is positioned close to, or at, a λ/8-operation point of the readout resonator, where λ is the wavelength of the readout resonator at a resonant frequency of the readout resonator.

5. The apparatus of claim 3, wherein the at least one readout resonator has a total length that is higher than a length of the hybrid coupler.

6. The apparatus of claim 1, wherein the readout resonator of an excited at least one quantum device is coupled to the transmission line simultaneously by the capacitive coupling and the inductive coupling.

7. The apparatus of claim 1, wherein the quantum device is a superconducting qubit.

8. A quantum computing system comprising the apparatus of claim 1.

9. The quantum computing system of claim 8, further comprising a control device operatively coupled to a transmission line and the at least one quantum device and the control device is configured to:
excite the at least one quantum device;
couple the readout resonator of the excited at least one quantum device to the transmission line based on a capacitive coupling and an inductive coupling;
read a readout signal comprising a waveform of the excited at least one quantum device at a readout band from the transmission line;
determine a state of at least one qubit based on the readout signal.

10. A method for the apparatus of claim 1, wherein the method comprises:
coupling the readout resonator of at least one quantum device to the transmission line based on a capacitive coupling and an inductive coupling.

11. A method for the quantum computing system of claim 8, comprising:
exciting the at least one quantum device;
coupling the readout resonator of at least one quantum device to the transmission line based on a capacitive coupling and an inductive coupling;
reading a readout signal comprising a waveform of the excited at least one quantum device at a readout band from the transmission line; and
determining a state of at least one qubit based on the readout signal.

12. The method of claim 11, wherein the readout resonator of the excited at least one quantum device is coupled to the transmission line simultaneously by the capacitive coupling and the inductive coupling.
